(19) United States
(12) Patent Application Publication
(10) Pub. No.: US 2025/0116002 A1
(43) Pub. Date: Apr. 10, 2025

(54) CERAMIC SUSCEPTOR

(71) Applicant: MiCo Ceramics Ltd., Anseong-si (KR)

(72) Inventor: Hyosung PARK, Anseong-si (KR)

(21) Appl. No.: 18/906,144

(22) Filed: Oct. 3, 2024

(30) Foreign Application Priority Data
Oct. 6, 2023 (KR) 10-2023-0133536

(51) Int. Cl. C23C 16/458; C23C 14/50; C23C 16/44

(52) U.S. Cl. CPC C23C 16/4586; C23C 14/50; C23C 16/4408

(57) ABSTRACT

Disclosed is a ceramic susceptor. The ceramic susceptor may include: an insulating plate having an electrode disposed thereon; a base body bonded to the insulating plate and having a purge flow path; a hollow shaft bonded to the base body and having at least one first through hole in a side wall thereof, wherein the at least one first through hole is in communication with the purge flow path; and a power supply rod connected to the electrode and extending through an internal space of the hollow shaft. The purge flow path may include: a calibration hole for flow path correction; a calibration flow path extending from the at least one first through hole to the calibration hole; and at least one flow path extending from the calibration hole to an edge.

### CROSS-REFERENCE TO RELATED APPLICATION(S)

This application is based on and claims priority under 35 U.S.C. 119 to Korean Patent Application No. 10-2023-0133536, filed on Oct. 6, 2023, in the Korean Intellectual Property Office, the disclosure of which is herein incorporated by reference in its entirety.

### BACKGROUND OF THE INVENTION

### 1. Field of the Invention

The present disclosure relates to a ceramic susceptor, and more particularly, to a ceramic susceptor in which air pumping for purging is uniformly performed over the entire top surface of a susceptor.

### 2. Description of the Prior Art

In general, a semiconductor device or a display device is manufactured through a semiconductor process of sequentially laminating a plurality of thin film layers including a dielectric layer and a metal layer on a glass substrate, a flexible substrate, or a semiconductor wafer substrate and then patterning the thin film layers. These thin film layers are sequentially deposited on the substrate through a chemical vapor deposition (CVD) process or a physical vapor deposition (PVD) process. The CVD process includes a low-pressure CVD (LPCVD) process, a plasma-enhanced CVD (PECVD) process, a metal-organic CVD (MOCVD) process, and the like. In the CVD and PVD apparatuses, a ceramic susceptor is placed to support a glass substrate, a flexible substrate, a semiconductor wafer substrate, or the like and to carry out the semiconductor process. The ceramic susceptor may include a chuck electrode installed in the CVD and PVD apparatuses to support a substrate, and a heating wire configured to heat the substrate in a heat treatment process or the like. In addition, the ceramic susceptor may include a radio frequency (RF) electrode instead of the heating wire, or may further include an RF electrode to be also used to form plasma during the etching process of the thin film layers formed on the substrate.

However, a conventional ceramic susceptor has a structure that does not allow purge gas to be supplied uniformly across its entire top surface where a substrate is placed when the purge gas is supplied through an array of purge holes or grooves on the top surface. Therefore, there is a need to improve this. That is, the purge structures of conventional ceramic susceptors may have a configuration where purging does not occur locally in specific directions or a configuration in which purging may occur locally to a large extent in specific directions. In such cases, during a deposition process or the like performed on a substrate on the ceramic susceptor provided in a chamber of the aforementioned apparatus, a thin film may be deposited unevenly, which may result in problems such as reduced yield or reduced deposition performance.

Therefore, there is a demand for a ceramic susceptor that enables uniform purging in all directions where a substrate is placed.

### SUMMARY OF THE INVENTION

The present disclosure has been made to solve the aforementioned problems, and provides a susceptor or ceramic susceptor in which a purging calibration hole is positioned at the center of the base body and the lengths of all fluid paths to the outermost edge are equal through radially symmetrical branching flow paths, so that air pumping for purging is performed uniformly across the entire top surface of the susceptor.

In addition, the present disclosure provides a susceptor or ceramic susceptor in which two flow paths formed in a shaft are respectively in fluid communication with a purging calibration hole and a chuck hole for vacuum pumping, so that the purging function by the purging calibration hole and the vacuum chuck function by the chuck hole can be comprehensively implemented.

In summary, a ceramic susceptor according to an aspect of the present disclosure may include: an insulating plate having an electrode disposed thereon; a base body bonded to the insulating plate and having a purge flow path; a hollow shaft bonded to the base body and having at least one first through hole in a side wall thereof, wherein the at least one first through hole is in communication with the purge flow path; and a power supply rod connected to the electrode and extending through an internal space of the hollow shaft. The purge flow path may include: a calibration hole for flow path correction; a calibration flow path extending from the at least one first through hole to the calibration hole; and at least one flow path extending from the calibration hole to an edge of the base body.

The at least one flow path may include a plurality of branch flow paths radially extending from the calibration hole to the edge of the base body.

The plurality of branch flow paths may be disposed symmetrically with respect to the calibration hole.

The calibration hole may be located at the center of the base body.

The at least one first through hole includes two or more through holes formed in the side wall of the hollow shaft, and respective calibration flow paths extending from the two or more through holes intersect at the calibration hole.

A purging function may be performed by maintaining the first through hole at a positive-pressure higher than atmospheric pressure.

The susceptor may further include a first through flow path penetrating between a top surface of the insulating plate and a bottom surface of the base body, and the hollow shaft further may include, in the side wall, at least one second through hole in communication with the first through flow path.

A substrate disposed on the insulating plate may be adsorbed by maintaining the second through hole at a negative-pressure lower than atmospheric pressure.

The electrode may be at least one of a plasma generation electrode, an electrostatic chuck electrode, or a heating element electrode.

The base body may include: a first layer including the calibration flow path extending from the at least one first through hole to the calibration hole; and a second layer including the calibration hole and the at least one flow path extending from the calibration hole to the edge of the base body.

The susceptor may further include a first through flow path penetrating through the first layer and the second layer from a top surface of the insulating plate, and the hollow shaft further may include, in the side wall, at least one second through hole in communication with the first through flow path.

The base body may include: a first layer including the calibration flow path extending from the at least one first through hole to the calibration hole; a second layer including the calibration hole; and a third layer including the at least one flow path extending from the calibration hole to the edge of the base body.

The susceptor may further include a first through flow path penetrating through the first layer, the second layer, and the third layer from a top surface of the insulating plate, and the hollow shaft further may include, in the side wall, at least one second through hole in communication with the first through flow path.

The base body may include a first layer including an entry hole in communication with the at least one first through hole, wherein the entry hole is a portion of the calibration flow path; a second layer including a connection flow path extending from the entry hole to the calibration hole and the calibration hole, wherein the connection flow path is a remaining portion of the calibration flow path; and a third layer including the at least one flow path extending from the calibration hole to the edge of the base body.

The susceptor may further include a first through flow path penetrating through the first layer, the second layer, and the third layer from a top surface of the insulating plate, and the hollow shaft further may include, in the side wall, at least one second through hole in communication with the first through flow path.

According to the ceramic susceptor of the present disclosure, by positioning the purging calibration hole at the center of the base body and forming all fluid paths to the outermost edge with equal lengths through radially symmetrical branching flow paths, air pumping for purging can be uniformly performed across the entire top surface of the susceptor. In this way, since purging is uniformly purged in all directions where a substrate is placed, a thin film can be uniformly deposited on the substrate during a deposition process or the like performed on the substrate on the ceramic susceptor, thereby increasing yield and improving deposition performance or the like.

In addition, according to the ceramic susceptor of the present disclosure, a flow path formed in the shaft and the purge correction hole of the susceptor are in fluid communication so that a uniform purging function is achieved on the entire top surface of the susceptor, and another flow path formed in the shaft is in fluid communication with a chuck hole for vacuum pumping of the susceptor so that a vacuum chuck function is additionally achieved, thereby implementing composite functions.

### BRIEF DESCRIPTION OF THE DRAWINGS

The accompanying drawings, which are included as part of a detailed description to aid the understanding of the present disclosure, provide embodiments of the present disclosure, and, together with the detailed description, illustrate the technical idea of the present disclosure, in which:

FIG. 1A is a schematic cross-sectional view of a ceramic susceptor according to a first embodiment of the present disclosure;

FIG. 1B is a schematic cross-sectional view of a ceramic susceptor according to a second embodiment of the present disclosure;

FIG. 1C is a schematic cross-sectional view of a ceramic susceptor according to a third embodiment of the present disclosure;

FIG. 2A illustrates an embodiment of constituent layers of a base body of the ceramic susceptor of FIG. 1A, and FIGS. 2B, 2C, 2D, and 2E illustrate top and bottom views each of the layers;

FIG. 3A illustrates an embodiment of constituent layers of a base body of the ceramic susceptor of FIG. 1A, and FIGS. 3B, 3C, 3D, and 3E illustrate top and bottom views each of the layers;

FIG. 4A illustrates another embodiment of constituent layers of a base body of the ceramic susceptor of FIG. 1A, and FIGS. 4B, 4C, 4D, 4E, 4F, and 4G illustrate top and bottom views each of the layers;

FIG. 5A illustrates another embodiment of constituent layers of a base body of the ceramic susceptor of FIG. 1A, and FIGS. 5B, 5C, 5D, 5E, 5F, and 5G illustrate top and bottom views each of the layers;

FIG. 6A illustrates still another embodiment of constituent layers of a base body of the ceramic susceptor of FIG. 1A, and FIGS. 6B, 6C, 6D, 6E, 6F, and 6G illustrate top and bottom views each of the layers; and

FIG. 7A illustrates yet another embodiment of constituent layers of a base body of the ceramic susceptor of FIG. 1B, and FIGS. 7B, 7C, 7D, 7E, 7F, and 7G illustrate top and bottom views each of the layers.

### DETAILED DESCRIPTION OF THE EXEMPLARY EMBODIMENTS

Hereinafter, the present disclosure will be described in detail with reference to the accompanying drawings. Herein, like components in each drawing are denoted by like reference numerals if possible. In addition, detailed descriptions of already known functions and/or configurations will be omitted. In the following description, components necessary for understanding operations according to various embodiments will be mainly described, and descriptions of elements that may obscure the gist of the description will be omitted. In addition, some elements in the drawings may be exaggerated, omitted, or schematically illustrated. The size of each component does not entirely reflect the actual size. Therefore, the descriptions provided herein are not limited by the relative sizes or spacings of the components drawn in each drawing.

In describing the embodiments of the present disclosure, when a detailed description of the known technology related to the present disclosure is determined to unnecessarily obscure the subject matter of the present disclosure, the detailed description will be omitted. In addition, terms to be described later are defined in consideration of functions in the present disclosure, and may vary according to the intention, custom, or the like of a user or operator. Therefore, the definitions of the terms should be made based on the description throughout this specification. Terms used in the detailed description are only for describing the embodiments of the present disclosure, and should not be construed as limiting in any way. Unless expressly used otherwise, singular expressions include the meanings of plural expressions. As used herein, expressions such as “including” or “comprising” are intended to indicate any features, numbers, steps, operations, elements, or some or combinations thereof, and should not be construed to exclude the existence or possibility of one or more other features, numbers, steps, operations, elements, or some or combinations thereof, in addition to those described above.

In addition, terms such as “first” and “second” may be used to describe various components, but the components are not limited by the terms, and these terms are only used for the purpose of distinguishing one component from another.

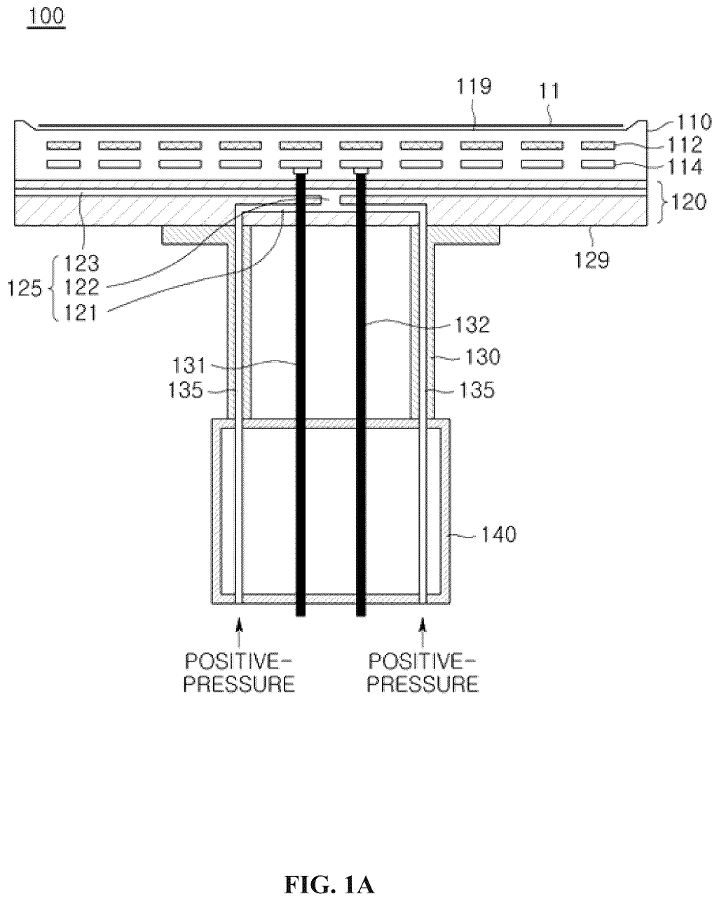

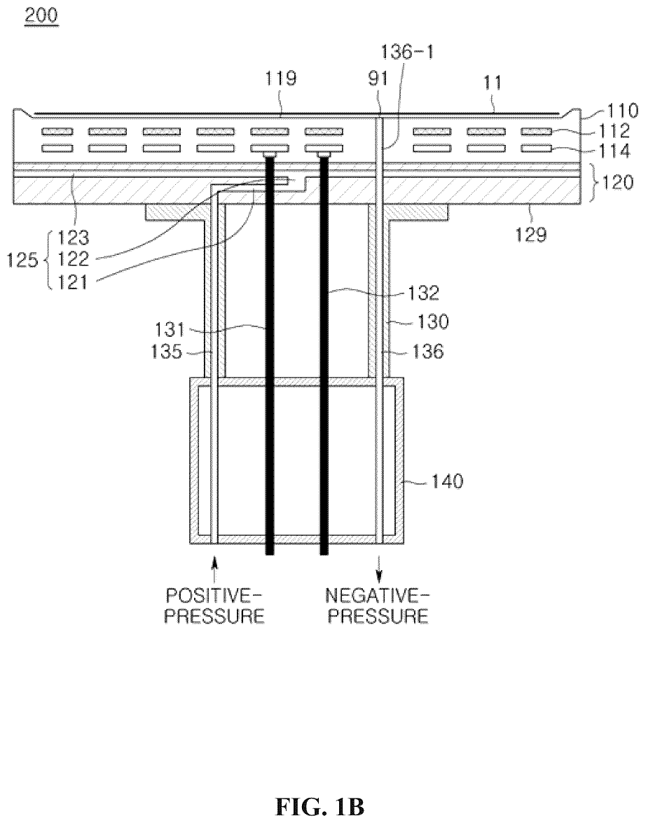

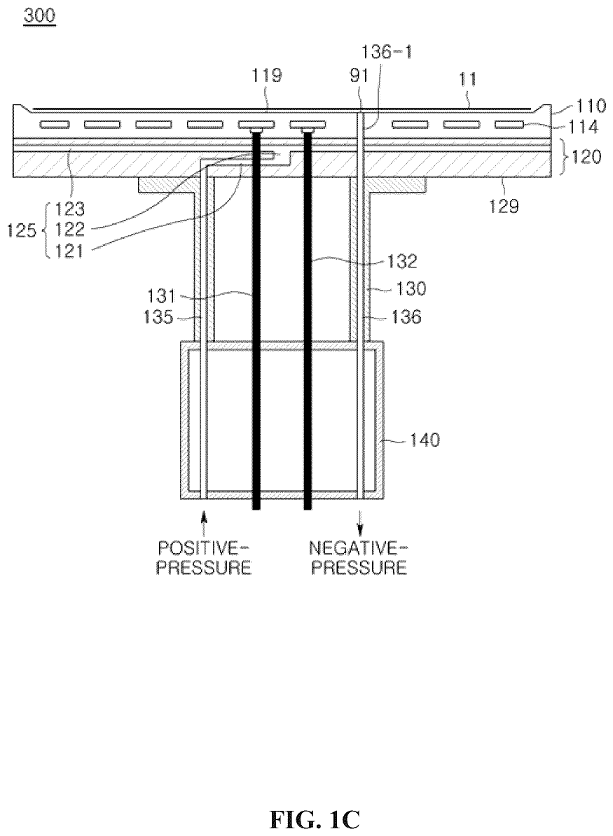

FIG. 1A is a schematic cross-sectional view of a ceramic susceptor 100 according to a first embodiment of the present disclosure.

FIG. 1B is a schematic cross-sectional view of a ceramic susceptor 200 according to a second embodiment of the present disclosure.

Referring to FIGS. 1A and 1B, the ceramic susceptor 200 according to the second embodiment is mostly the same as the ceramic susceptor 100 according to the first embodiment, but further includes a first through flow path 136-1 that penetrates between a top surface 119 of an insulating plate 110 and a bottom surface 129 of a base body 120. The first through flow path 136-1 provides a chuck hole 91 for vacuum pumping on the top surface of the insulating plate 110, and a substrate 11 placed on the insulating plate 110 may be adsorbed and supported through the chuck hole 91.

FIG. 1C is a schematic cross-sectional view of a ceramic susceptor 300 according to a third embodiment of the present disclosure.

Referring to FIG. 1C, the ceramic susceptor 300 according to the third embodiment of the present disclosure is a modification of the ceramic susceptor 200 according to the second embodiment, where an electrode 112 is omitted, while the remaining components are the same as those of the ceramic susceptor 200 of the second embodiment.

That is, the (ceramic) susceptors 100, 200, and 300 of the present disclosure each include an insulating plate 110 and a base body 120 that are bonded using an adhesive such as ceramic paste, and under the bonded body of the insulating plate 110 and the base body 120, a hollow shaft 130 bonded using an adhesive such as ceramic paste to support the bonded body is included. In some cases, a connection mount 140 may be used at the lower portion of the shaft 130 to facilitate connection to a system, such as a chamber of a semiconductor apparatus.

Individual rods 131, 132, and so on may be accommodated in the internal space of the shaft 130 and may be connected to an electrode 112 and/or the heating element 114 embedded in the insulating plate 110 to supply necessary power. The individual rods 131, 132, and so on may extend from the internal space of the shaft 130 through the connection mount 140, which is sealed on the outside (e.g., a rigid body or a member having a hollow space), and protrude outside.

The ceramic susceptors 100, 200, and 300 of the present disclosure may each have a heater function to heat a processing target substrate 11 to a predetermined temperature during a semiconductor process using the heating element 114. In addition, the ceramic susceptors 100 and 200 of the present disclosure may each include an electrode 112, which may be used as a chuck electrode for the electrostatic chuck function to support a substrate 11 placed on the insulating plate 110, or as a plasma electrode for plasma generation in a process such as plasma-enhanced chemical vapor deposition (PECVD) or dry etching in a reactive ion etching (RIE) apparatus. This is a separate function from the vacuum chuck function that supports the substrate 11 through vacuum pumping via the chuck hole 91.

To achieve this, the insulating plate 110 is configured to have the heating element 114 disposed (embedded) between ceramic materials, and in some cases, the electrode 112 may also be disposed (embedded) at a predetermined distance from the heating element 114. In some cases, chuck electrode(s) may be further disposed (embedded) above or below the heating element 114 at a predetermined distance.

As described above, the insulating plate 110 may be configured to support a processing target substrate stably, while enabling various semiconductor processes through heating using the heating element 114 and/or providing an electrostatic chuck function, a plasma generation function or the like using the electrode 112. The insulating plate 110 may be a plate-like structure having a predetermined shape. For example, the insulating plate 110 may be a circular plate-like structure, but is not necessarily limited thereto. Here, the ceramic material may be at least one of Al₂O₃, Y₂O₃, Al₂O₃/Y₂O₃, ZrO₂, autoclaved lightweight concrete (AlC), TiN, AlN, TiC, MgO, CaO, CeO₂, TiO₂, BₓC_{y}, BN, SiO₂, SiC, YAG, mullite, and AlF₃, preferably aluminum nitride (AlN). Furthermore, the powder of the ceramic material may be molded and sintered to provide the insulating plate 110, and each ceramic powder for this purpose may optionally contain about 0.1 to 10%, preferably about 1 to 5% of yttrium oxide powder.

In addition, the heating element 114 may have a plate-shaped coil shape or a flat plate shape with a heating wire (or a resistance wire). In addition, the heating element 114 may be fabricated in a multi-layer structure for precise temperature control. The heating element 114 is connected to a power source via the power supply rods 131 and 132, and power is supplied to perform the function of heating the processing target substrate 11 on the insulating plate 110 to a predetermined temperature for a process such as substrate heating, deposition, or etching in a semiconductor process. The power supply rods 131 and 132 pass through the internal space of the shaft 130, penetrate a predetermined isolation plate of the mount 140, and extend outward through the mount 140.

The electrode 112 may be made of tungsten (W), molybdenum (Mo), silver (Ag), gold (Au), niobium (Nb), titanium (Ti), aluminum nitride (AlN), or an alloy thereof, preferably molybdenum (Mo). The electrode 112 may be connected to a power terminal (e.g., ground) via a separate power supply rod (not illustrated) other than the power supply rods 131 and 132 for the heating element 114. The power supply rod (not shown) for the electrode 112 may also pass through the internal space of the shaft 130, penetrate a predetermined isolation plate of the mount 140, and extend outward through the mount 140.

The shaft 130 is hollow, having a penetrating internal space, and is coupled to the bottom surface of the bonded structure of the insulating plate 110 and the base body 120. The shaft 130 may be made of the same ceramic material as the insulating plate 110 and may be bonded to the same. Here, the ceramic material may be at least one of Al₂O₃, Y₂O₃, Al₂O₃/Y₂O₃, ZrO₂, autoclaved lightweight concrete (AlC), TiN, AlN, TiC, MgO, CaO, CeO₂, TiO₂, BₓC_{y}, BN, SiO₂, SiC, YAG, mullite, and AlF₃, preferably aluminum nitride (AlN). Furthermore, the powder of the ceramic material may be molded and sintered to provide the shaft 130, and each ceramic powder for this purpose may optionally contain about 0.1 to 10%, preferably about 1 to 5% of yttrium oxide powder.

The connection mount 140 may be made of a metal material, such as aluminum (Al), or may be made of a ceramic material as described above. The ceramic material may be at least one of Al₂O₃, Y₂O₃, Al₂O₃/Y₂O₃, ZrO₂, autoclaved lightweight concrete (AlC), TiN, AlN, TiC, MgO, CaO, CeO₂, TiO₂, BₓC_{y}, BN, SiO₂, SiC, YAG, mullite, and AlF₃, preferably aluminum nitride (AlN). Furthermore, the powder of the ceramic material may be molded and sintered to provide the shaft 130, and each ceramic powder for this purpose may optionally contain about 0.1 to 10%, preferably about 1 to 5% of yttrium oxide powder.

Referring again to FIGS. 1A to 1C, the base body 120 bonded under the insulating plate 110 has a purge flow path 125. The upper end of the side wall of the hollow shaft 130 is bonded to the base body 120, and the shaft 130 has, in the side wall, at least one first through hole 135 in communication with the purge flow path 125. The base body 120 may be made of a ceramic material. Here, the ceramic material may be at least one of Al₂O₃, Y₂O₃, Al₂O₃/Y₂O₃, ZrO₂, autoclaved lightweight concrete (AlC), TIN, AlN, TIC, MgO, CaO, CeO₂, TiO₂, BₓC_{y}, BN, SiO₂, SiC, YAG, mullite, and AlF₃, preferably aluminum nitride (AlN). Furthermore, the powder of the ceramic material may be molded and sintered to provide the shaft 130, and each ceramic powder for this purpose may optionally contain about 0.1 to 10%, preferably about 1 to 5% of yttrium oxide powder.

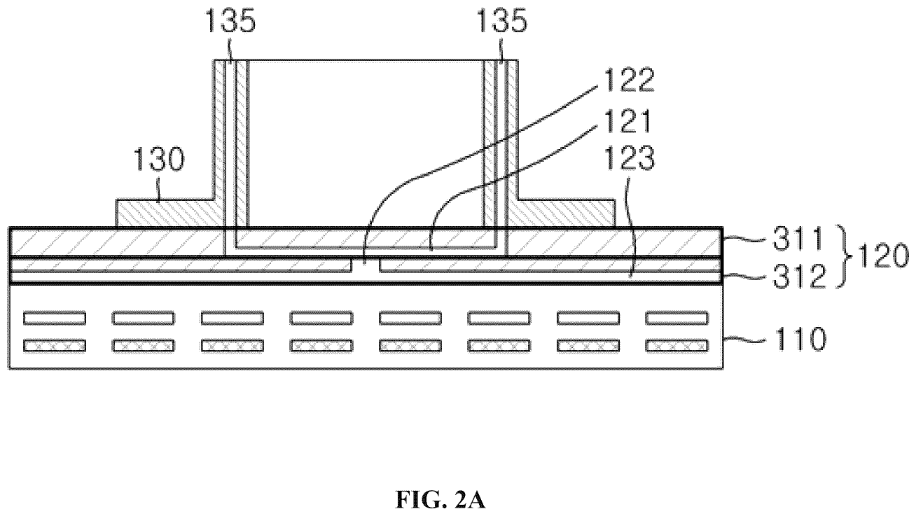

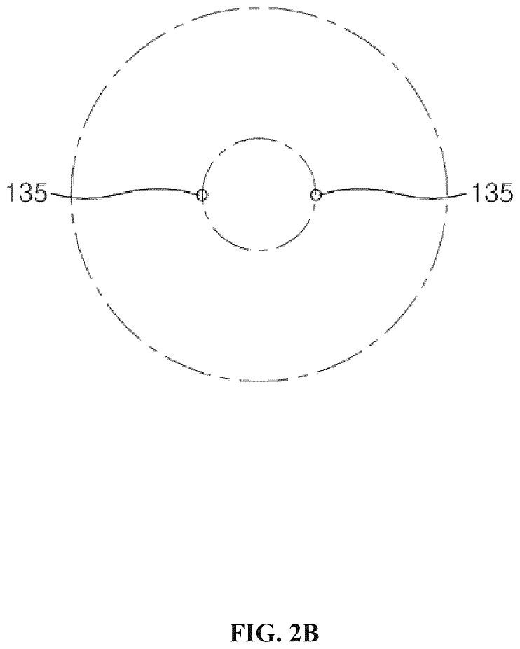

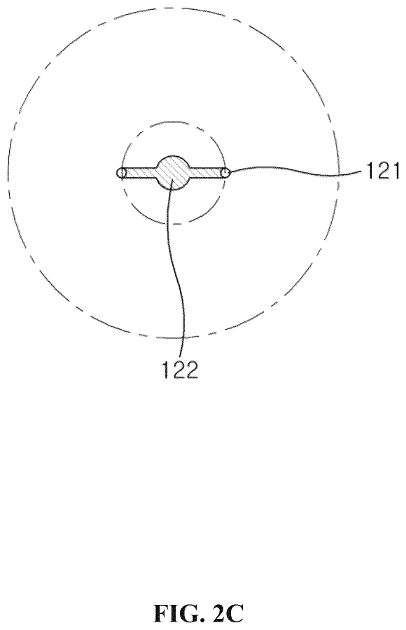

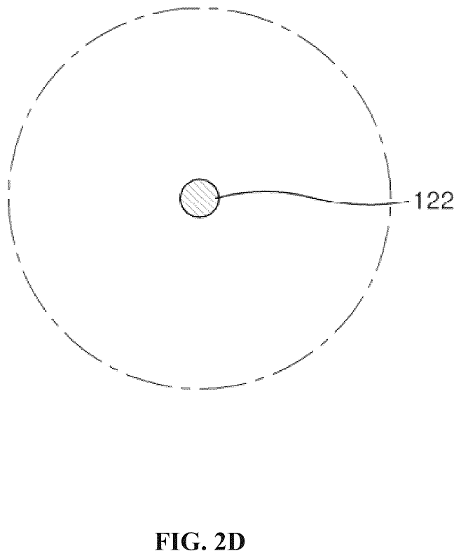

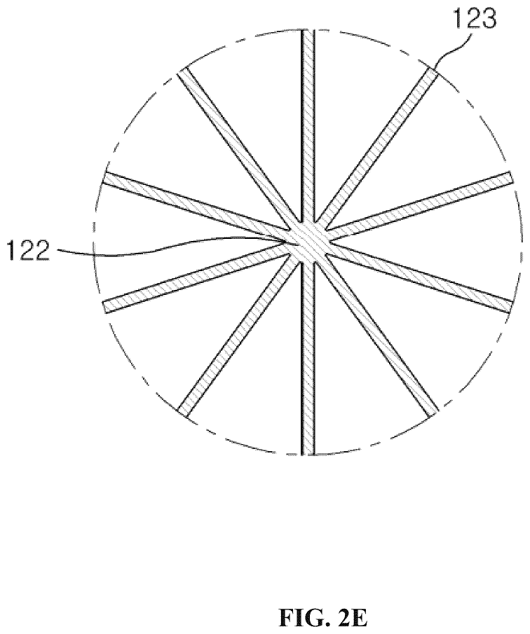

The purge flow path 125 includes a calibration flow path 121, a calibration hole 122, and a plurality of branching flow paths 123. The calibration flow path 121 is a flow path portion that extends from the first through hole 135 of the shaft 130 to the calibration hole 122 for path correction. The calibration hole 122 may be designed to have a predetermined diameter larger than the diameter of the calibration flow path 121, and may have a suitable vertical height on the top surface of the insulating plate 110. The branching flow paths 123 extend radially from the calibration hole 122 to the edge (see FIGS. 2E, 3E, 4F, 5F, 6F, and 7F).

As will be explained in more detail below, the calibration hole 122 is preferably located at the center of the base body 120, although it may be disposed at other locations in some cases. In addition, the plurality of branching flow paths 123 are configured to be connected to/in communication with the calibration hole 122 and are preferably disposed symmetrically around the calibration hole 122. While the at least one first through hole 135 formed in the side wall of the shaft 130 is illustrated as two in the drawings, only one through hole or an appropriate number of three or more through holes may also be formed in the side wall of the shaft 130. Respective calibration flow paths 121 extending from the plurality of through holes 135 may intersect at the calibration hole 122 and extend radially, like the branching flow paths 123.

The purging function may be performed by maintaining the first through holes 135 at a positive-pressure higher than atmospheric pressure. For example, the purging function may be performed by maintaining the first through holes 135 in the shaft 130 at a pressure higher than atmospheric pressure through positive-pressure air pumping. At this time, a predetermined air pump (not illustrated) may perform pumping by injecting air at a predetermined pressure higher than atmospheric pressure through the first through holes 135. For example, in the chambers of the aforementioned CVD and PVD apparatuses, purging may be performed by blowing air containing a predetermined gas (e.g., nitrogen gas, or an inert gas such as He or Ar) by positive-pressure air pumping through the first through holes 135.

Meanwhile, in addition to the common features of the ceramic susceptors 100, 200, and 300 mentioned above, in the case of FIG. 1B, the ceramic susceptor 200 of the second embodiment further includes a first through flow path 136-1 penetrating between the top surface 119 of the insulating plate 110 and the bottom surface 129 of the base body 120. Correspondingly, the shaft 130 may further include, in the side wall, at least one second through hole 136 in communication with the first through flow path 136-1.

By maintaining the second through hole 136 at a negative-pressure lower than atmospheric pressure, a vacuum chuck function may be performed to adsorb the substrate 11 placed on the insulating plate 110. That is, the first through flow path 136-1 provides a chuck hole 91 for vacuum pumping on the top surface of the insulating plate 110, and a substrate 11 placed on the insulating plate 110 may be adsorbed and supported through the chuck hole 91.

For example, the at least one chuck hole 91 exposed on the top surface of the insulating plate 110 may intersect grooves formed on the top surface of the insulating plate 110. The grooves formed on the top surface of the insulating plate 110 may be configured in various ways to adsorb and support the substrate 11 through the negative-pressure from the at least one chuck hole 91. For example, the grooves formed on the top surface of the insulating plate 110 may be designed to be connected throughout so that the substrate 11 can be stably adsorbed through the negative-pressure from the chuck hole 91.

As described above, the ceramic susceptor 200 of the present disclosure enables chucking and dechucking of the substrate 11 through negative-pressure air pumping via the second through hole 136. At the this time, the ceramic susceptor may be configured to enable various semiconductor processes, such as deposition or dry etching using heating by the heating element 114 and using plasma generated by the electrode 112, while stably supporting the processing target substrate 11 on the insulating plate 110.

The ceramic susceptors 100, 200, and 300 according to embodiments of the present disclosure each have a purging calibration hole 122 at the center of the base body 120 and all fluid paths are formed to have the same length to the outermost edge of the insulating plate 110 by radially symmetrical branching flow paths 123, so that air pumping for purging can be uniformly performed across the entire top surface of the susceptor.

Additionally, in the case of FIGS. 1B and 1C, in the ceramic susceptor 200 of the second embodiment, a flow path formed in the shaft is in fluid communication with the purging calibration hole 122 in the susceptor so that uniform purging is achieved across the entire top surface of the susceptor and another flow path 136 formed in the shaft 130 is in fluid communication with the chuck hole for vacuum pumping so that a vacuum chuck function is additionally achieved. Thus, composite functions can be implemented.

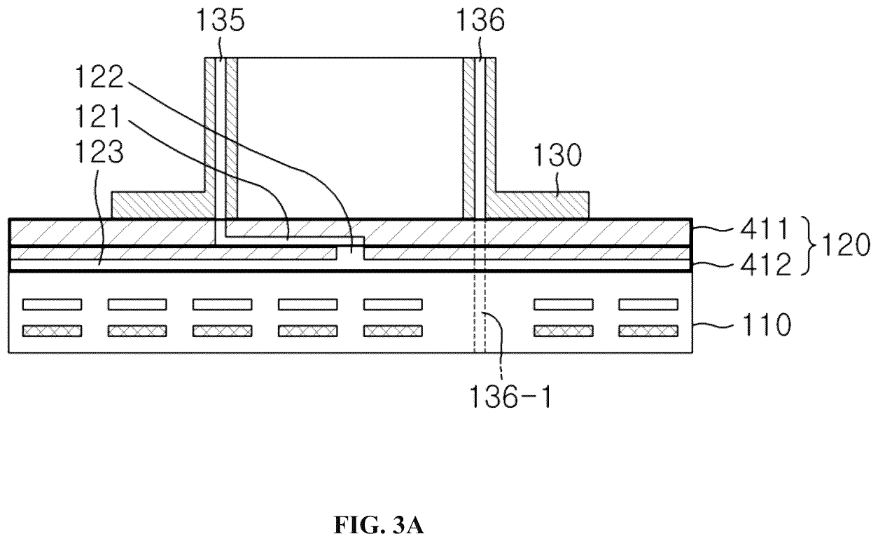

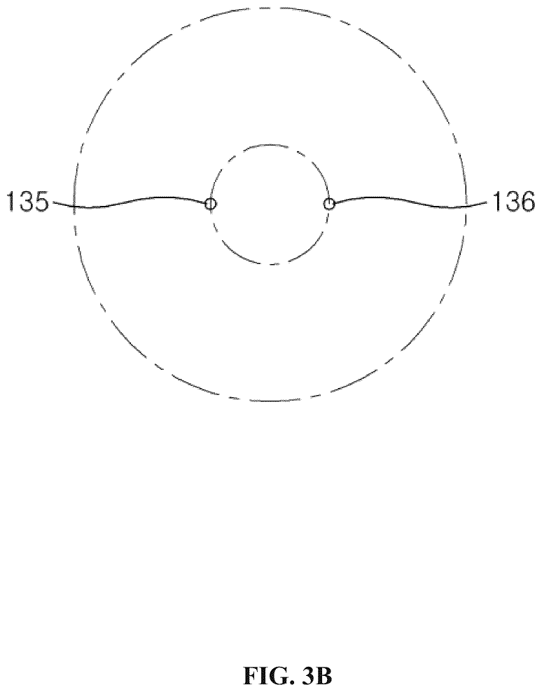

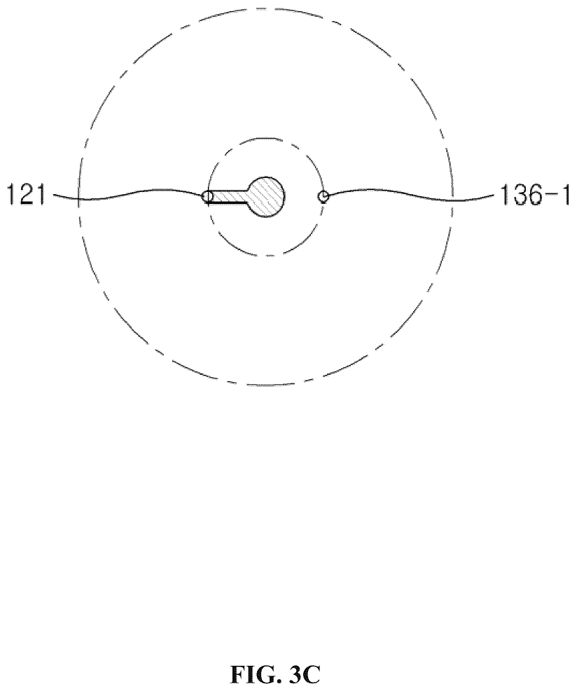

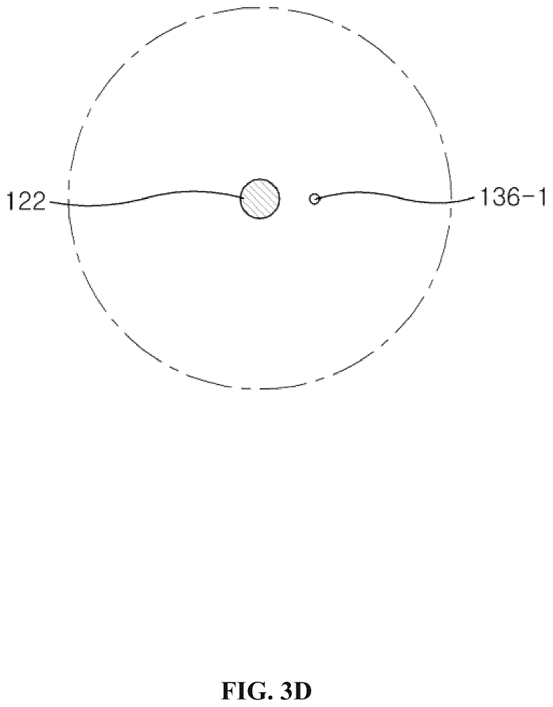

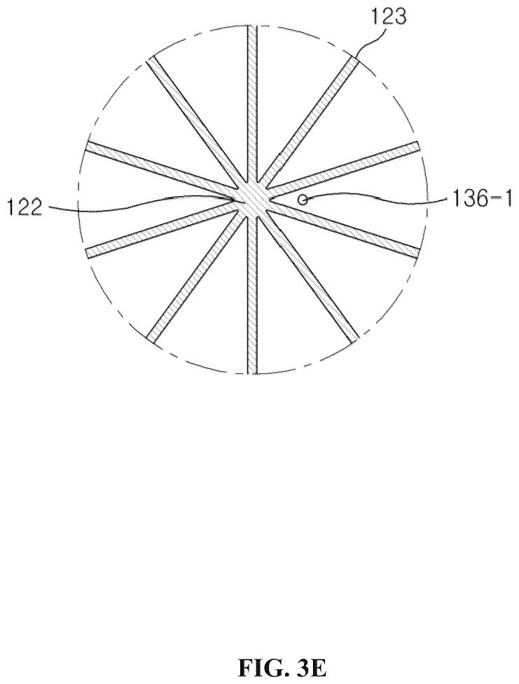

Hereinafter, with reference to FIGS. 2A to 2E, FIGS. 4A to 4G, and FIGS. 6A to 6G (which are enlarged views of FIG. 1A, flipped upside down), the ceramic susceptor 100 of the first embodiment of the present disclosure will be described in more detail, and with reference to FIGS. 3A to 3E, FIGS. 5A to 5G, and FIGS. 7A to 7G (which are enlarged views of FIG. 1B, flipped upside down), the ceramic susceptors 200 and 300 of the second and third embodiments of the present disclosure will be described in more detail. The ceramic susceptor 300 according to the third embodiment is a modification of the ceramic susceptor 200 of the second embodiment in which the electrode 112 is omitted, and thus a person ordinarily skilled in the art will easily understand the ceramic susceptor 300 of the third embodiment by referring to the structure of the ceramic susceptor 200 according to the second embodiment.

FIG. 2A illustrates an embodiment of the constituent layers 311 and 312 of the base body 120 of the ceramic susceptor 100 of FIG. 1A, FIGS. 2B and 2C illustrate the top view and bottom view, respectively, of the first layer 311, and FIGS. 2D and 2E illustrate the top view and bottom view, respectively, of the second layer 312.

Referring to FIG. 2A, the base body 120 of the ceramic susceptor 100 of the present disclosure may include the first layer 311 and the second layer 312. The first layer 311 and the second layer 312 may be manufactured separately and bonded with ceramic paste or the like, or may be stacked using molding and sintering of each layer when loading material powder or laminating multiple sheets.

Referring to FIGS. 2B and 2C, the first layer 311 may include the calibration flow path 121 extending from at least one first through hole 135 of the shaft 130 to the calibration hole 122.

Referring to FIGS. 2D and 2E, the second layer 312 may include the calibration hole 122 and the plurality of branching flow paths 123 extending radially from the calibration hole 122 to the edge of the base body 120/insulating plate 110.

FIG. 3A illustrates an embodiment of the constituent layers 311 and 312 of the base body 120 of the ceramic susceptor 200 of FIG. 1B, FIGS. 3B and 3C illustrate the top view and bottom view, respectively, of the first layer 311, and FIGS. 3D and 3E illustrate the top view and bottom view, respectively, of the second layer 312.

Referring to FIG. 3A, the base body 120 of the ceramic susceptor 200 of the present disclosure may include the first layer 411 and the second layer 412. The first layer 411 and the second layer 412 may be manufactured separately and bonded with ceramic paste or the like, or may be stacked using molding and sintering of each layer when loading material powder or laminating multiple sheets.

The structure of the ceramic susceptor 200 of the present disclosure of FIG. 3A is similar to the structure of FIG. 2A, but further includes a first through flow path 136-1 penetrating the first layer 411 and the second layer 412 from the top surface of the insulating plate 110. The first through-flow path 136-1 is disposed at a different position so that it does not intersect or communicate with the calibration flow path 121 or the branching flow paths 123 along its path. At this time, the shaft 130 further includes, in the side wall, at least one second through hole 136 in communication with the first through flow path 136-1. The first through hole 135 and the second through hole 136 in the shaft 130 do not communicate with each other.

Referring to FIGS. 3B and 3C, the first layer 411 may include the calibration flow path 121 extending from at least one first through hole 135 of the shaft 130 to the calibration hole 122.

Referring to FIGS. 3D and 3E, the second layer 412 may include the calibration hole 122 and the plurality of branching flow paths 123 extending radially from the calibration hole 122 to the edge of the base body 120/insulating plate 110.

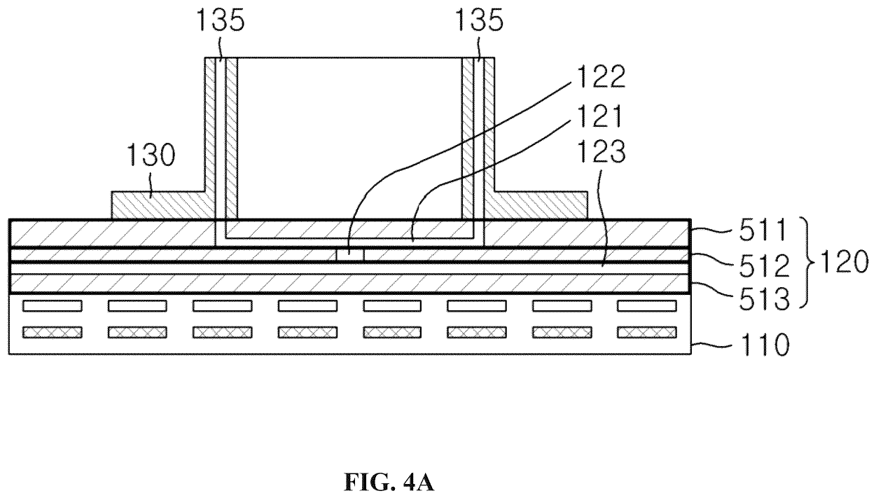

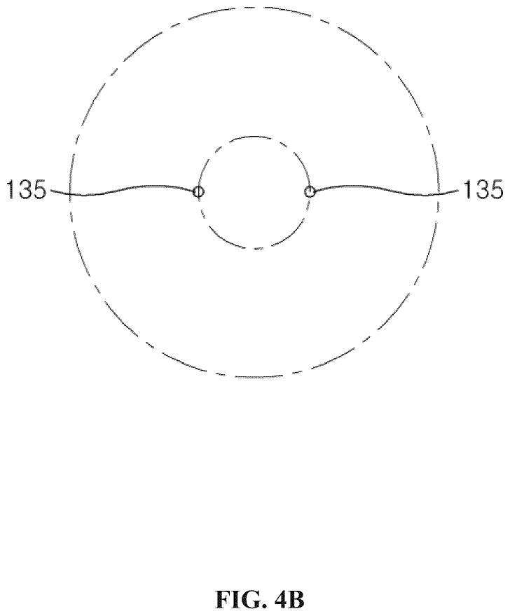

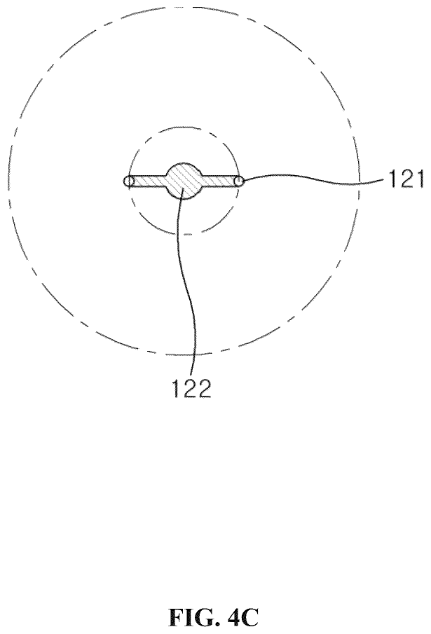

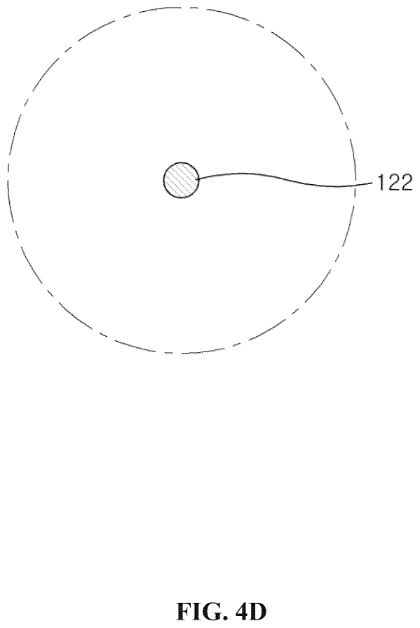

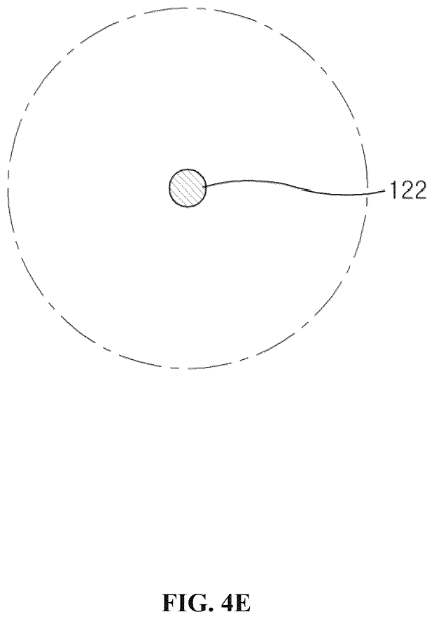

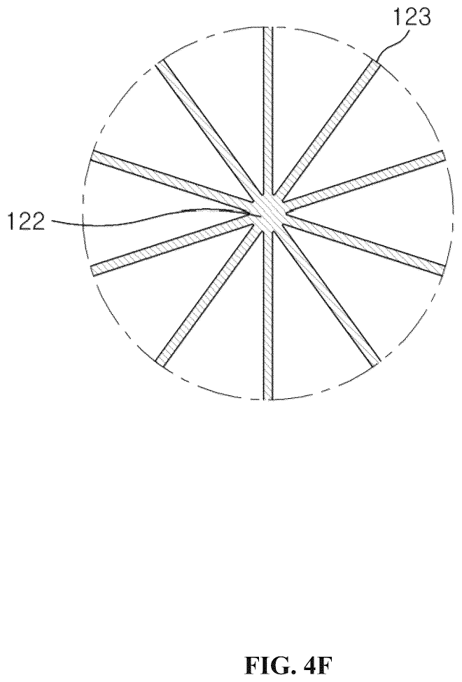

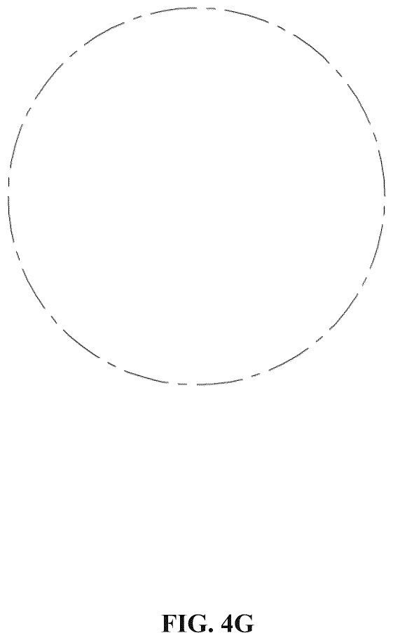

FIG. 4A illustrates an embodiment of the constituent layers 511, 512, and 513 of the base body 120 of the ceramic susceptor 100 in FIG. 1A, FIGS. 4B and 4C illustrate the top view and bottom view, respectively, of a first layer 511, FIGS. 4D and 4E illustrate the top view and bottom view, respectively, of a second layer 512, and FIGS. 4F and 4G illustrate the top view and bottom view, respectively, of a third layer 513.

Referring to FIG. 4A, the base body 120 of the ceramic susceptor 100 of the present disclosure may include the first layer 511, the second layer 512, and the third layer 513. The first layer 511, the second layer 512, and the third layer 513 may be manufactured separately and bonded with ceramic paste or the like, or may be stacked using molding and sintering of each layer when loading material powder or laminating multiple sheets.

Referring to FIGS. 4B and 4C, the first layer 511 includes the calibration flow path 121 extending from at least one first through hole 135 to the calibration hole 122.

Referring to FIGS. 4D and 4E, the second layer 512 is the layer where the calibration hole 122 is formed.

Referring to FIGS. 4F and 4G, the third layer 513 include the plurality of branching flow paths 123 extending radially from the calibration hole 122 to the edge of the base body 120/insulating plate 110.

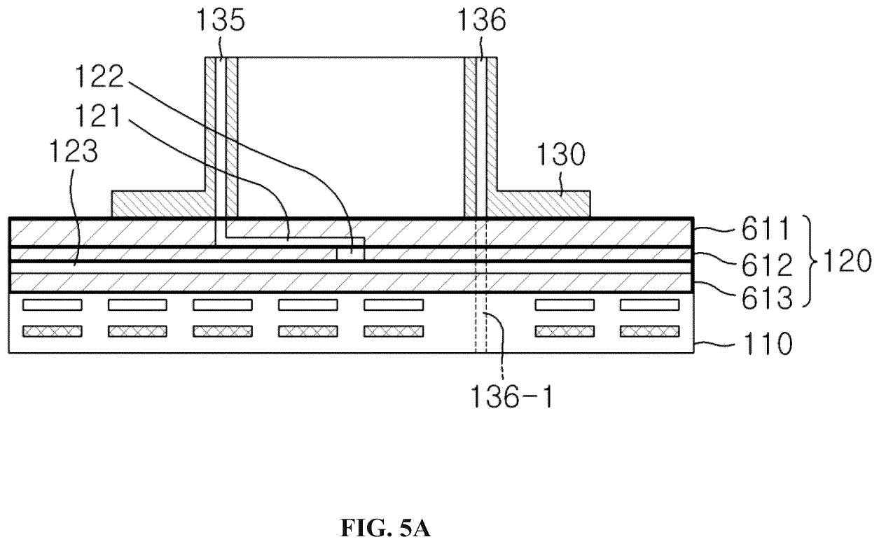

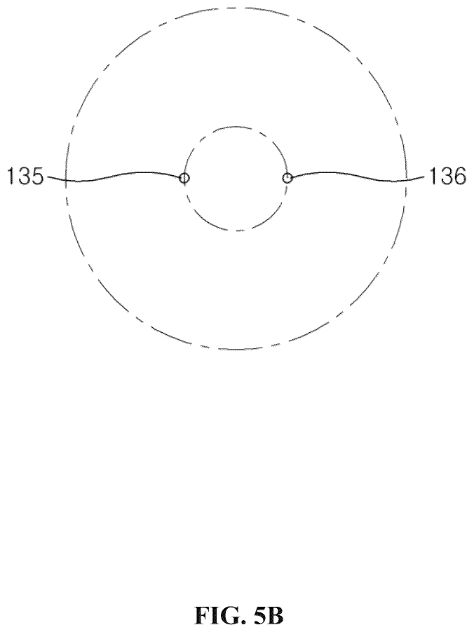

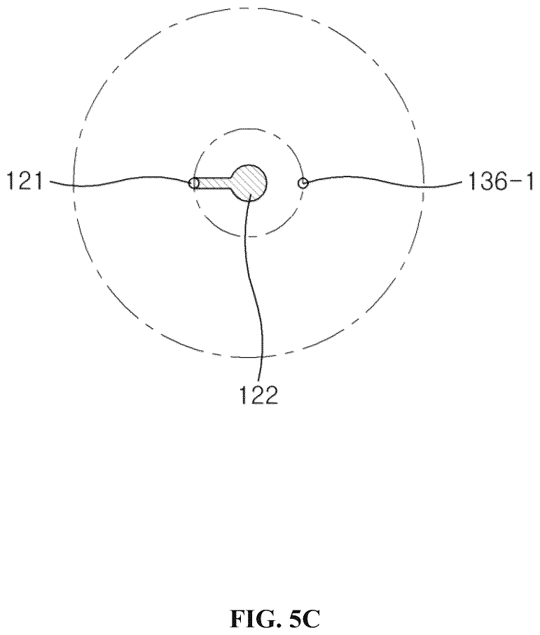

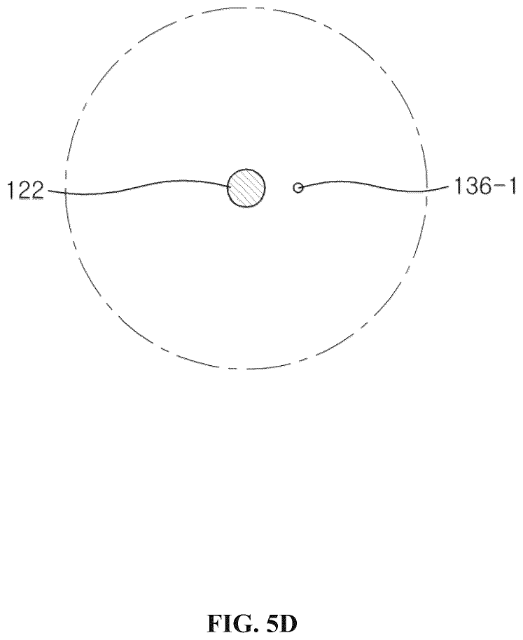

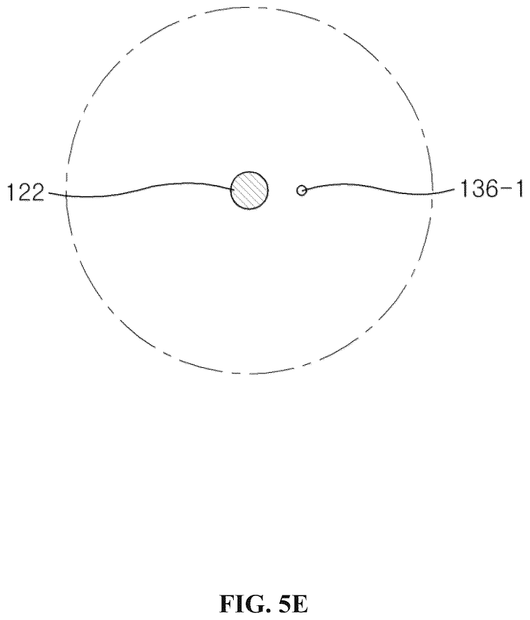

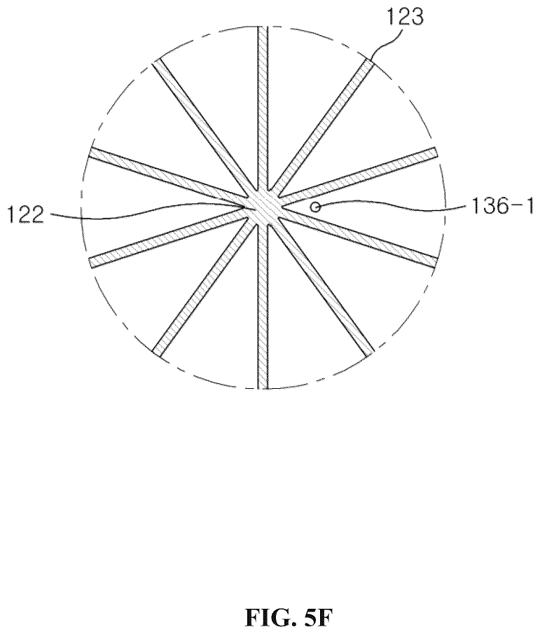

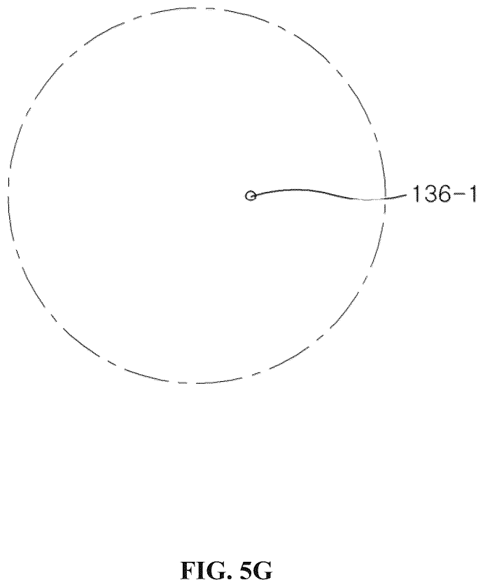

FIG. 5A illustrates an embodiment of the constituent layers 611, 612, and 613 of the base body 120 for the ceramic susceptor 200 in FIG. 1B, FIGS. 5B and 5C illustrate the top view and bottom view, respectively, of a first layer 611, FIGS. 5D and 5E illustrate the top view and bottom view, respectively, of a second layer 612, and FIGS. 5F and 5G illustrate the top view and bottom view, respectively, of a third layer 613.

Referring to FIG. 5A, the base body 120 of the ceramic susceptor 200 of the present disclosure may include the first layer 611, the second layer 612, and the third layer 613. The first layer 611, the second layer 612, and the third layer 613 may be manufactured separately and bonded with ceramic paste or the like, or may be stacked using molding and sintering of each layer when loading material powder or laminating multiple sheets.

The structure of the ceramic susceptor 200 of the present disclosure of FIG. 5A is similar to the structure of FIG. 4A, but further includes a first through flow path 136-1 penetrating the first layer 611, the second layer 612, and the third layer 613 from the top surface of the insulating plate 110. The first through-flow path 136-1 is disposed at a different position so that it does not intersect or communicate with the calibration flow path 121 or the branching flow paths 123 along its path. At this time, the shaft 130 further includes, in the side wall, at least one second through hole 136 in communication with the first through flow path 136-1. The first through hole 135 and the second through hole 136 in the shaft 130 do not communicate with each other.

Referring to FIGS. 5B and 5C, the first layer 611 includes the calibration flow path 121 extending from at least one first through hole 135 to the calibration hole 122.

Referring to FIGS. 5D and 5E, the second layer 612 is the layer where the calibration hole 122 is formed.

Referring to FIGS. 5F and 5G, the third layer 513 include the plurality of branching flow paths 123 extending radially from the calibration hole 122 to the edge of the base body 120/insulating plate 110.

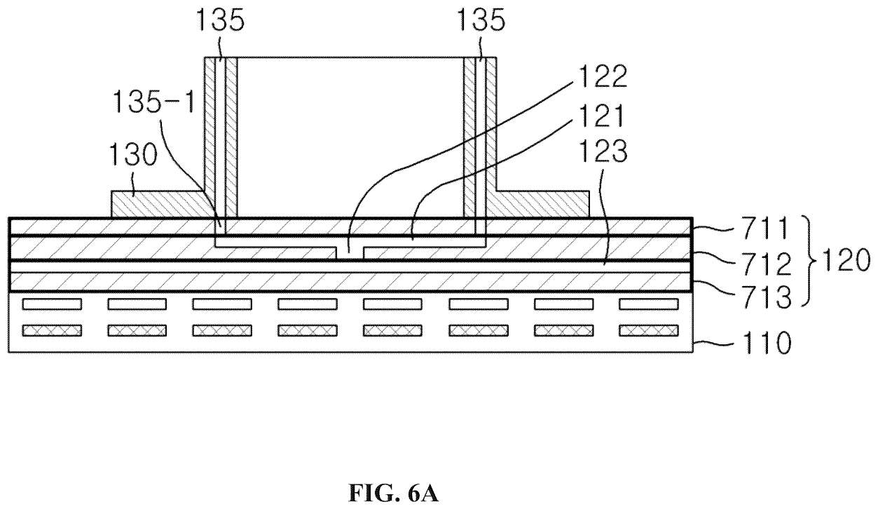

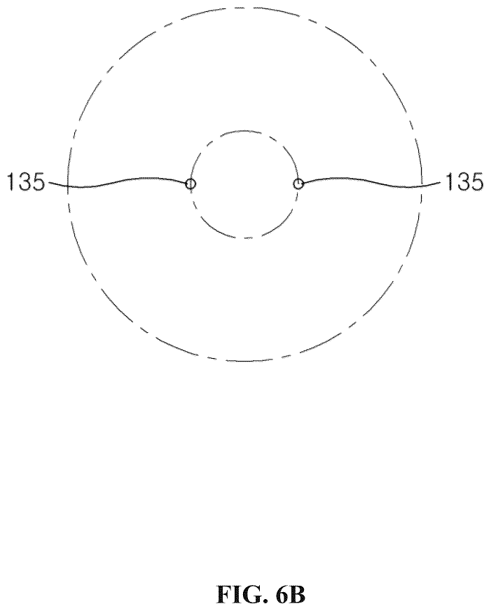

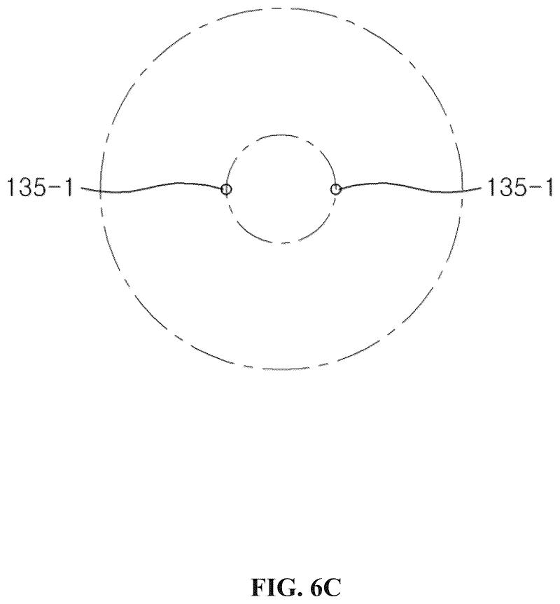

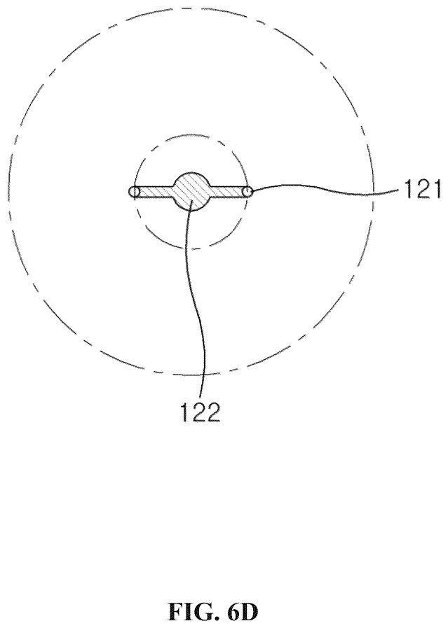

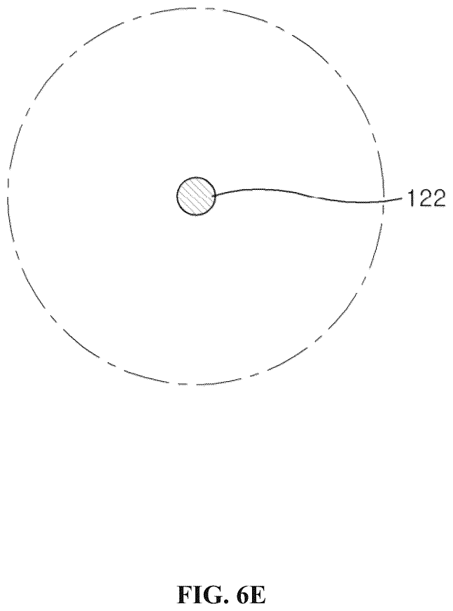

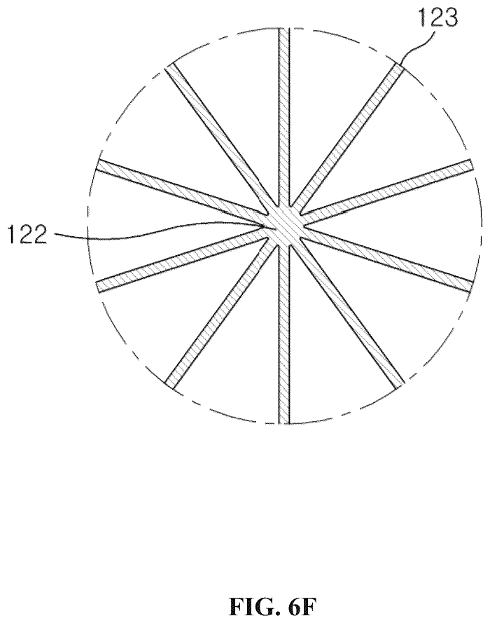

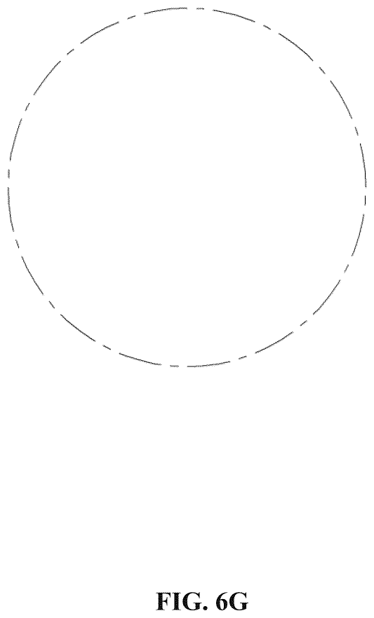

FIG. 6A illustrates an embodiment of the constituent layers 711, 712, and 713 of the base body 120 of the ceramic susceptor 100 in FIG. 1A, FIGS. 6B and 6C illustrate the top view and bottom view, respectively, of a first layer 711, FIGS. 6D and 6E illustrate the top view and bottom view, respectively, of a second layer 712, and FIGS. 6F and 6G illustrate the top view and bottom view, respectively, of a third layer 713.

Referring to FIG. 6A, the base body 120 of the ceramic susceptor 100 of the present disclosure may include the first layer 711, the second layer 712, and the third layer 713. The first layer 711, the second layer 712, and the third layer 713 may be manufactured separately and bonded with ceramic paste or the like, or may be stacked using molding and sintering of each layer when loading material powder or laminating multiple sheets.

Referring to FIGS. 6B and 6C, the first layer 711 includes an entry hole 135-1 that communicates with at least one first through hole 135. The entry hole 135-1 is a portion of the calibration flow path 121.

Referring to FIGS. 6D and 6E, the second layer 711 includes a connection flow path that extends from the entry hole 135-1 to the calibration hole 122. The connection flow path is the remaining portion of the calibration flow path 121 and also includes the calibration hole 122.

Referring to FIGS. 6F and 6G, the third layer 713 include the plurality of branching flow paths 123 extending radially from the calibration hole 122 to the edge of the base body 120/insulating plate 110.

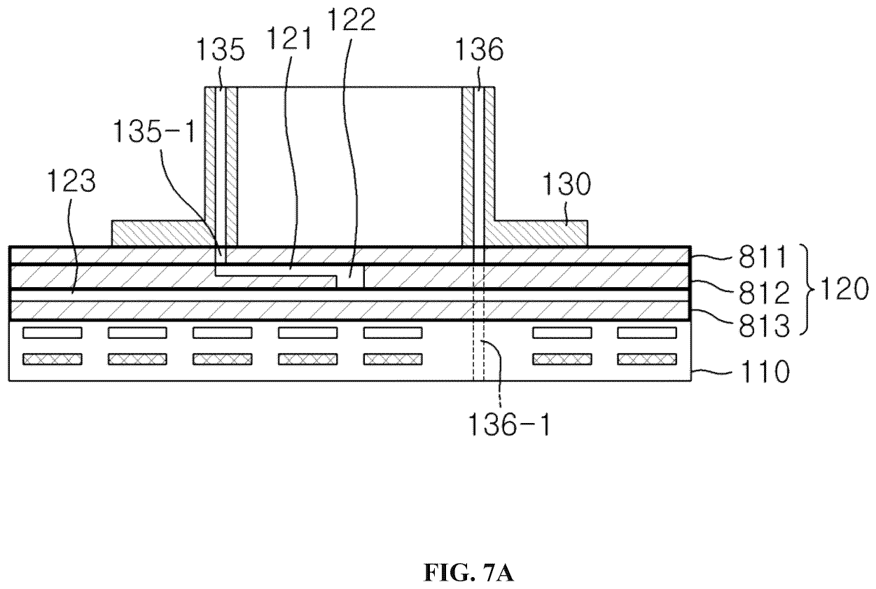

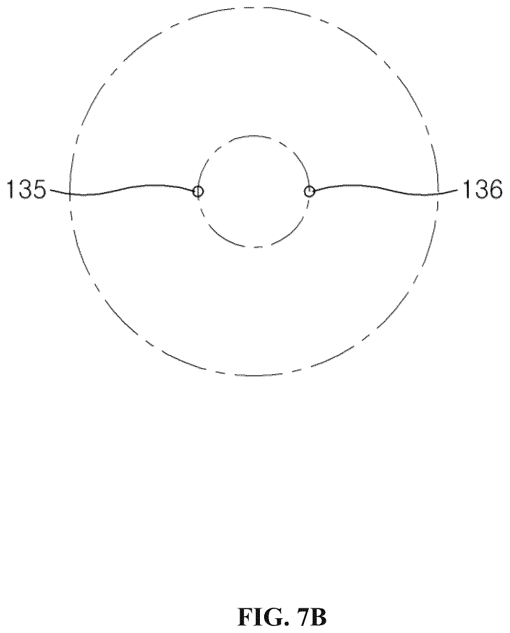

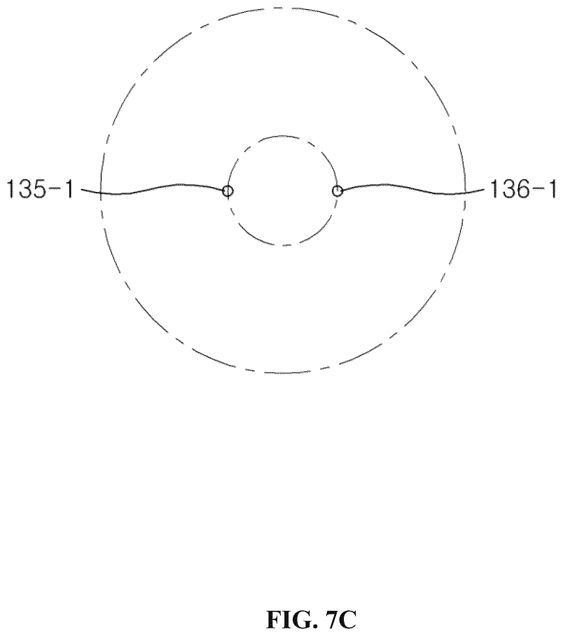

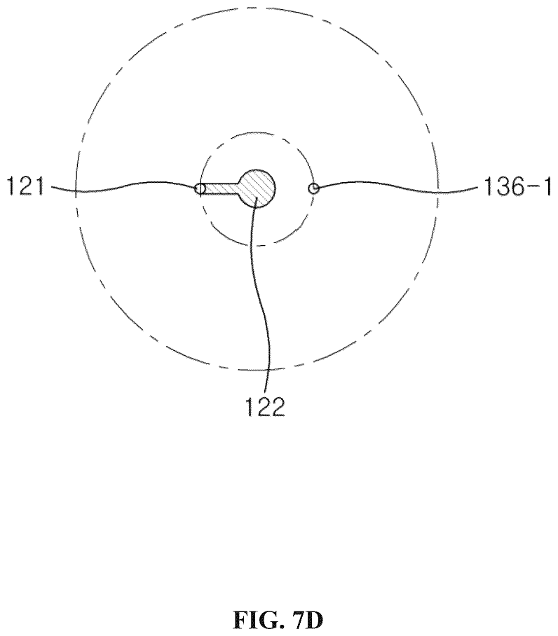

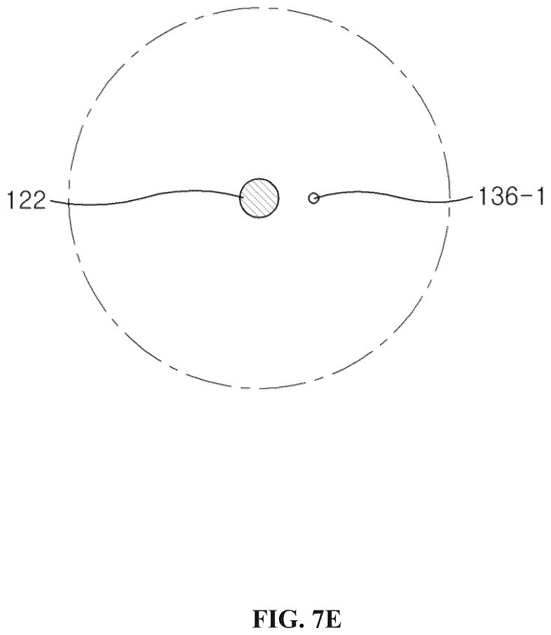

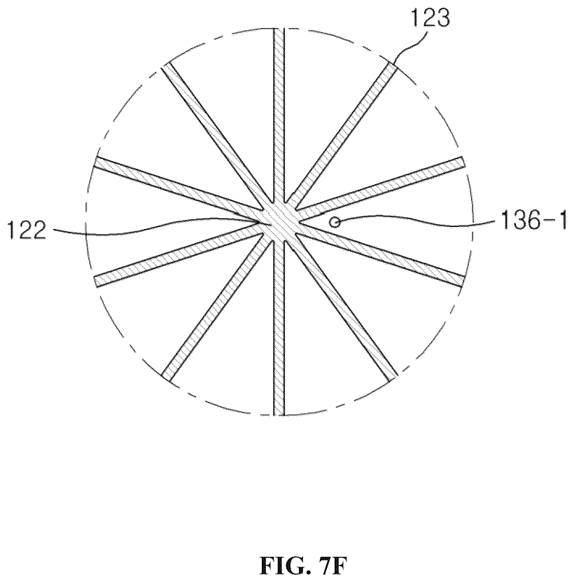

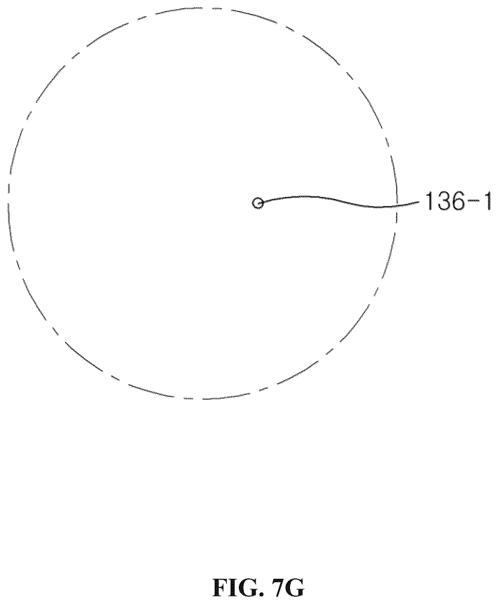

FIG. 7A illustrates an embodiment of the constituent layers 811, 812, and 813 of the base body 120 for the ceramic susceptor 200 in FIG. 1B, FIGS. 7B and 7C illustrate the top view and bottom view, respectively, of a first layer 811, FIGS. 7D and 7E illustrate the top view and bottom view, respectively, of a second layer 812, and FIGS. 7F and 7G illustrate the top view and bottom view, respectively, of a third layer 813.

Referring to FIG. 7A, the base body 120 of the ceramic susceptor 200 of the present disclosure may include the first layer 811, the second layer 812, and the third layer 813. The first layer 811, the second layer 812, and the third layer 813 may be manufactured separately and bonded with ceramic paste or the like, or may be stacked using molding and sintering of each layer when loading material powder or laminating multiple sheets.

The structure of the ceramic susceptor 200 of the present disclosure of FIG. 7A is similar to the structure of FIG. 6A, but further includes a first through flow path 136-1 penetrating the first layer 811, the second layer 812, and the third layer 813 from the top surface of the insulating plate 110. The first through-flow path 136-1 is disposed at a different position so that it does not intersect or communicate with the calibration flow path 121 or the branching flow paths 123 along its path. At this time, the shaft 130 further includes, in the side wall, at least one second through hole 136 in communication with the first through flow path 136-1. The first through hole 135 and the second through hole 136 in the shaft 130 do not communicate with each other.

Referring to FIGS. 7B and 7C, the first layer 811 includes an entry hole 135-1 that communicates with at least one first through hole 135. The entry hole 135-1 is a portion of the calibration flow path 121.

Referring to FIGS. 7D and 7E, the second layer 811 includes a connection flow path that extends from the entry hole 135-1 to the calibration hole 122. The connection flow path is the remaining portion of the calibration flow path 121 and also includes the calibration hole 122.

Referring to FIGS. 7F and 7G, the third layer 813 include the plurality of branching flow paths 123 extending radially from the calibration hole 122 to the edge of the base body 120/insulating plate 110.

As described above, the ceramic susceptors 100, 200, and 300 according to embodiments of the present disclosure each have a purging calibration hole 122 at the center of the base body 120 and all fluid paths are formed to have the same length to the outermost edge of the insulating plate 110 by radially symmetrical branching flow paths 123, so that air pumping for purging can be uniformly performed across the entire top surface of the susceptor. In this way, since purging is uniformly performed in all directions where a substrate is placed, a thin film can be uniformly deposited on the substrate during a deposition process or the like performed on the substrate on the ceramic susceptor, thereby increasing yield and improving deposition performance or the like. Additionally, in the case of FIG. 1B, in the ceramic susceptor 200 of the second embodiment, a flow path formed in the shaft is in fluid communication with the purging calibration hole 122 in the susceptor so that uniform purging is achieved across the entire top surface of the susceptor and another flow path 136 formed in the shaft 130 is in fluid communication with the chuck hole for vacuum pumping of the susceptor so that a vacuum chuck function is additionally achieved. Thus, composite functions can be implemented.

In the foregoing, the present disclosure has been described based on specific details, such as concrete components, limited embodiments, and drawings, but these have been provided merely to aid a more comprehensive understanding of the present disclosure, and the present disclosure is not limited to the above-described embodiments. Various modifications and alterations may be made without departing from the essential characteristics of the present disclosure by a person ordinarily skilled in the art to which the present disclosure pertains. Therefore, the spirit of the present disclosure should not be limited to the described embodiments, and not only the appended claims, but also all technical ideas that are equivalent or have equivalent modifications to the claims should be construed as being included within the scope of the present disclosure.

What is claimed is:

1. A susceptor comprising:
an insulating plate having an electrode disposed thereon;
a base body bonded to the insulating plate and having a purge flow path;
a hollow shaft bonded to the base body and having at least one first through hole in a side wall thereof, wherein the at least one first through hole is in communication with the purge flow path; and
a power supply rod connected to the electrode and extending through an internal space of the hollow shaft,
wherein the purge flow path comprises:
a calibration hole for flow path correction;
a calibration flow path extending from the at least one first through hole to the calibration hole; and
at least one flow path extending from the calibration hole to an edge of the base body.

2. The susceptor of claim 1, wherein the at least one flow path comprises a plurality of branch flow paths radially extending from the calibration hole to the edge of the base body.

3. The susceptor of claim 2, wherein the plurality of branch flow paths are disposed symmetrically with respect to the calibration hole.

4. The susceptor of claim 1, wherein the calibration hole is located at a center of the base body.

5. The susceptor of claim 1, wherein the at least one first through hole comprises two or more through holes formed in the side wall of the hollow shaft, and
wherein respective calibration flow paths extending from the two or more through holes intersect at the calibration hole.

6. The susceptor of claim 1, wherein the susceptor is configured to perform a purging function by maintaining the at least one first through hole at a positive-pressure higher than atmospheric pressure.

7. The susceptor of claim 1, further comprising:
a first through flow path penetrating between a top surface of the insulating plate and a bottom surface of the base body,
wherein the hollow shaft further comprises, in the side wall, at least one second through hole in communication with the first through flow path.

8. The susceptor of claim 7, wherein the susceptor is configured to adsorb a substrate disposed on the insulating plate by maintaining the at least one second through hole at a negative-pressure lower than atmospheric pressure.

9. The susceptor of claim 1, wherein the electrode is at least one of a plasma generation electrode, an electrostatic chuck electrode, or a heating element electrode.

10. The susceptor of claim 1, wherein the base body comprises:
a first layer comprising the calibration flow path extending from the at least one first through hole to the calibration hole; and
a second layer comprising the calibration hole and the at least one flow path extending from the calibration hole to the edge of the base body.

11. The susceptor of claim 10, further comprising:
a first through flow path penetrating through the first layer and the second layer from a top surface of the insulating plate,
wherein the hollow shaft further comprises, in the side wall, at least one second through hole in communication with the first through flow path.

12. The susceptor of claim 1, wherein the base body comprises:
a first layer comprising the calibration flow path extending from the at least one first through hole to the calibration hole;
a second layer comprising the calibration hole; and
a third layer comprising the at least one flow path extending from the calibration hole to the edge of the base body.

13. The susceptor of claim 12, further comprising:
a first through flow path penetrating through the first layer, the second layer, and the third layer from a top surface of the insulating plate,
wherein the hollow shaft further comprises, in the side wall, at least one second through hole in communication with the first through flow path.

14. The susceptor of claim 1, wherein the base body comprises:
a first layer comprising an entry hole in communication with the at least one first through hole, wherein the entry hole is a portion of the calibration flow path;
a second layer comprising a connection flow path extending from the entry hole to the calibration hole and the calibration hole, wherein the connection flow path is a remaining portion of the calibration flow path; and
a third layer comprising the at least one flow path extending from the calibration hole to the edge of the base body.

15. The susceptor of claim 14, further comprising:
a first through flow path penetrating through the first layer, the second layer, and the third layer from a top surface of the insulating plate,
wherein the hollow shaft further comprises, in the side wall, at least one second through hole in communication with the first through flow path.
